(19) United States
(12) Patent Application Publication
(10) Pub. No.: US 2025/0194221 A1
(43) Pub. Date: Jun. 12, 2025

(54) TRANSITION METAL DICHALCOGENIDE INTERLAYERS FOR IMPROVED ELECTRICAL DEVICE PERFORMANCE

(71) Applicant: VERSUM MATERIALS US, LLC, TEMPE, AZ (US)

(72) Inventor: SERGEY BARABASH, SAN JOSE, CA (US)

(21) Appl. No.: 18/970,614

(22) Filed: Dec. 5, 2024

Related U.S. Application Data
(60) Provisional application No. 63/608,059, filed on Dec. 8, 2023.

(51) Int. Cl. H10D 64/68; H10D 1/00; H10D 1/68

(52) U.S. Cl. CPC H10D 64/685; H10D 1/041; H10D 1/68

(57) ABSTRACT

A semiconductor device such as a capacitor or transistor has an interface layer comprising a metallic transition metal dichalcogenide material. The interface layer may be formed adjacent to the dielectric layer and may include a monolayer, a bilayer, or more layers of one or more metallic transition metal dichalcogenides. The interface layer is incorporated in a capacitor stack and is preferably deposited using atomic layer deposition.

### CROSS-REFERENCE TO RELATED APPLICATIONS

This application claims priority to U.S. Provisional Patent Application No. 63/608,059, filed Dec. 8, 2023. The entire contents of which is incorporated herein by reference in its entirety.

### FIELD

The disclosed and claimed subject matter relates generally to interlayers deposited using vapor techniques, including atomic layer deposition (ALD). More specifically, the disclosed and claimed subject matter relates to capacitors, transistors, and other electronic devices having thin film interlayers that contain transition metal dichalcogenides and methods for preparing and depositing these materials. Significantly, devices fabricated with these materials exhibit improved tradeoff between leakage and capacitance properties.

### BACKGROUND

There is tradeoff between leakage and capacitance in both in capacitors (e.g., DRAM) and in transistor gate stacks. Capacitance is inversely proportional to thickness and thus thickness should be reduced to increase capacitance, while various leakage mechanisms each lead to a strong (e.g., exponential) increase in leakage as the thickness is reduced. High-k dielectrics are used as a way to increase capacitance without decreasing leakage, but continued scaling requires further increases in capacitance. A need exists to scale further without increasing leakage.

Leakage is a key issue both in capacitors (e.g., DRAM) and in transistor gate stacks. The two ways typically utilized to decrease leakage are (i) decreasing the number of defects in the dielectric, by optimizing stack composition and deposition/processing method and conditions), and (ii) optimizing the barrier at the dielectric-electrode interface, by optimizing the effective work function of the electrode, by introducing interface control layers (ICLs), and/or optimizing the deposition/processing method and conditions). When ICLs are used, such layers can be insulating. acting as a part of the dielectric, or conducting, acting as a part of the electrode.

Few-nanometer films of high-k dielectrics, including ZrO₂, HfO₂ and HfₓZr₁₋ₓO₂ have different functional properties depending on the thickness and crystal structure of the film. The high-k tetragonal crystal phase of ZrO₂, is difficult to crystallize in few-nanometer films, and the leakage current through the device scales strongly with thickness. Leakage and capacitance are also strongly influenced by the interfacial states that are formed 1) when the dielectric layer is grown on a conductive electrode material (e.g., TiN) called bottom electrode layer (BEL) and 2) when a conductive electrode material (e.g., TiN) is grown on top of the dielectric layer, called top electrode layer (TEL).

The performance of the interfaces between the dielectric and both electrodes is a function of processing conditions during device fabrication including but not limited to: 1) the temperature of each deposition step; 2) intentional dopants or unintentional impurities incorporated into the layers through the deposition; 3) the local crystallization, grain size, and surface roughness of each layer; and 4) the temperature and duration of additional heat treatment annealing conducted between the deposition of each layer or after all layers are deposited.

Known electrode-dielectric-electrode stacks seek to reduce leakage current and equivalent oxide thickness (EOT, i.e., increase capacitance) for thinner dielectric layers. For instance, in ZrO₂ stacks an additional dielectric layer, such as Al₂O₃ layer, is often used (termed ZAZ stack) to interrupt crystalline domains and break continuous grain boundaries which traverse the film between top and bottom electrodes. These grain boundaries present charge transport pathways and interrupting them with a ZAZ configuration reduces leakage current. Beyond grain boundary engineering, additional metal oxide (additional i.e., beyond the major metal specie in the dielectric stack) can be used to stabilize dielectric crystalline phases with higher k. Without the addition of these dopants, it can be difficult to stabilize the desired phase in the low thickness films of interest. It is frequently observed that decreasing leakage increases EOT (i.e., decreases capacitance) and vice versa: for instance, ZAZ stacks have reduced leakage while but EOT compared to pure ZrO₂ stacks of the same thickness, because Al₂O₃ has a lower dielectric constant compared to ZrO₂.

A need exists to provide an improved stack to address leakage and capacitance shortcomings associated with the best known methods.

### SUMMARY

In a first main aspect, a capacitor is provided. The capacitor comprising: a first electrode; a second electrode; a dielectric layer between the first electrode and the second electrode; and an interface layer, wherein the interface layer comprises a metallic transition metal dichalcogenide.

In a further aspect of the first main aspect, the metallic transition metal dichalcogenide comprises NbS₂, NbSe₂, NbTe₂, TaS₂, TaSe₂, TaTe₂, or combinations thereof. In a further aspect of the first main aspect, the dielectric layer comprises ZrO₂, HfO₂, TiO₂, MoO₂, or combinations thereof.

In a further aspect of the first main aspect, the interface layer has a thickness ranging from about 5 Å to about 20 Å.

In a further aspect of the first main aspect, the interface layer is disposed between the second electrode and the dielectric layer.

In a further aspect of the first main aspect, the interface layer is disposed between the first electrode and the dielectric layer.

In a further aspect of the first main aspect, the interface layer is a bilayer. In a further aspect of the first main aspect, the bilayer comprises a first layer of the metallic transition metal dichalcogenide and a second layer of a second metallic transition metal dichalcogenide.

In a further aspect of the first main aspect, a further interface layer is provided between the first electrode and the dielectric film, between the second electrode and the dielectric film, between the interface layer and the first electrode, or between the interface layer and the second electrode; and wherein the further interface layer comprises an oxide of a metal element.

In a further aspect of the first main aspect, the second electrode is a bottom electrode comprising a metal nitride represented by MN, wherein M is a metal element, and wherein N is nitrogen.

In a further aspect of the first main aspect, the further interface layer comprises a metal oxynitride represented by M′OxNy, wherein M′ is a metal element, wherein N is nitrogen, and wherein O is oxygen.

In a further aspect of the first main aspect, the bottom electrode comprises TiN. In a further aspect of the first main aspect, M is Be, B, Na, Mg, Al, Si, K, Ca, Sc, Ti, V, Cr, Mn, Fe, Co, Ni, Cu, Zn, Ga, Ge, Rb, Sr, Y, Zr, Nb, Mo, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, or Bi. In a further aspect of the first main aspect, M′ is Li, Be, B, N, Na, Mg, Al, Si, P, K, Ca, Sc, Ti, V, Cr, Mn, Fe, Co, Ni, Cu, Zn, Ga, Ge, As, Sc, Rb, Sr, Y, Zr, Nb, Mo, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, or B.

In a further aspect of the first main aspect, the first electrode directly contacts a bottom surface of the interface layer, and the dielectric film directly contacts a top surface of the interface layer; and/or wherein the second electrode directly contacts a top surface of the interface layer, and the dielectric film directly contacts a bottom surface of the interface layer. In a further aspect of the first main aspect, the first electrode is a top electrode or the second electrode is the bottom electrode, and both the top electrode and bottom electrode can be independently selected from the group consisting of titanium nitride, molybdenum nitride, cobalt nitride, tantalum nitride, titanium aluminum nitride, tantalum aluminum nitride, tungsten, ruthenium, ruthenium oxide, strontium ruthenium oxide, iridium, iridium oxide, platinum, platinum oxide, silver, gold, barium, boron, calcium, lanthanum, or a combination thereof.

In a second main aspect, a semiconductor device is provided. The semiconductor device comprising: a semiconducting material; a gate structure on the semiconducting material; a first source/drain region and a second source/drain region, both arranged in upper portions of the semiconducting material; and the gate structure comprising a gate dielectric disposed on the semiconducting material, an interface layer disposed on the gate dielectric, and a gate conductor disposed on the interface layer; and wherein the interface layer comprises a metallic transition metal dichalcogenide.

In a further aspect of the second main aspect, the interface layer has a thickness of between about 5 Å and about 20 Å, more preferably from about 6 Å to about 12 Å.

In a further aspect of the second main aspect, the bottom electrode comprises a metal nitride represented by MN, wherein M is a metal element, and wherein N is nitrogen; and wherein M is chosen from the group consisting of Li, Be, B, N, Na, Mg, Al, Si, P, K, Ca, Sc, Ti, V, Cr, Mn, Fc, Co, Ni, Cu, Zn, Ga, Ge, As, Se, Rb, Sr, Y, Zr, Nb, Mo, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, and Bi.

In a further aspect of the second main aspect, the interface layer is a bilayer; and wherein the bilayer comprises a first layer of the metallic transition metal dichalcogenide and a second layer of the metallic transition metal dichalcogenide; or wherein the bilayer comprises a first layer of the metallic transition metal dichalcogenide and a second layer of a second metallic transition metal dichalcogenide.

In a further aspect of the second main aspect, the metallic transition metal dichalcogenide comprises NbS₂, NbSe₂, NbTe₂, TaS₂, TaSe₂, TaTe₂, or combinations thereof.

In a further aspect of the second main aspect, the gate dielectric directly contacts a bottom surface of the interface layer, and the gate conductor directly contacts a top surface of the interface layer.

In a third main aspect, a method of fabricating a capacitor is provided. The method comprising: (a) forming a first electrode; (b) forming a dielectric film; (c) forming a second electrode; and (d) forming one or more interface layers, wherein one of the one or more interface layers comprises a metallic transition metal dichalcogenide; and wherein step (d) is performed after step (a) or after step (b).

In a further aspect of the third main aspect, the method further comprises forming one or more further interface layers comprising the metallic transition metal dichalcogenide or a further metallic transitional metal dichalcogenide.

In a fourth main aspect, a method of fabricating a capacitor is provided. The method comprising: forming a first electrode by atomic layer deposition; forming a dielectric layer by atomic layer deposition; forming one or more interface layers comprising a metallic transition metal dichalcogenide by atomic layer deposition; and forming a second electrode by atomic layer deposition.

In a further aspect of the fourth main aspect, the method further comprises forming one or more further interface layers comprising the metallic transition metal dichalcogenide or a further metallic transitional metal dichalcogenide.

In a further aspect of any of the foregoing aspects, the metallic transition metal dichalcogenide or the further metallic transition metal dichalcogenide comprises NbS₂, NbSe₂, TaS₂, TaSe₂, or combinations thereof.

In a fifth main aspect, a method of forming a capacitor is provided. The method comprising: a. forming a first electrode; b. forming a dielectric material on the first electrode; c. forming a metallic transition metal dichalcogenide material using an atomic layer deposition process using a transition metal precursor as a first precursor and a chalcogenide as a second precursor; d. annealing the bottom electrode, the dielectric material, and the transition metal dichalcogenide material thereby forming transition metal dichalcogenide layer; and e. forming a second electrode on the transition metal dichalcogenide layer.

In a further aspect of any of the foregoing aspects, the method further comprises patterning the capacitor into a capacitor array.

In a sixth main aspect, an integrated circuit device is provided. The integrated circuit device comprising: a first electrode; a second electrode; a dielectric layer between the first electrode and the second electrode; and a metallic transition metal dichalcogenide interface layer adjacent to the dielectric layer.

In a sixth main aspect, a memory device is provided. The memory device comprising: an array of memory cells, one of the memory cells comprising an access transistor and a capacitor, wherein the capacitor comprises: a first electrode; a second electrode; a dielectric layer disposed between the first electrode and the second electrode; and a transition metal dichalcogenide interlayer interposed between the dielectric layer and the first electrode or the second electrode.

In a further aspect of the second main aspect, the semiconductor device further comprises a first source/drain region and a second source/drain region, both arranged in upper portions of the semiconducting material. In a further aspect of the second main aspect, the semiconductor device is a transistor. In a further aspect of the second main aspect, the semiconductor device is a power switch.

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The order of discussion of the different steps described herein has been presented for clarity sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1A illustrates a capacitor structure in accordance with an embodiment of the instant disclosure;

FIG. 1B illustrates an alternative embodiment of a capacitor structure disclosed herein;

FIG. 2 illustrates a transistor structure in accordance with an embodiment of the instant disclosure;

FIG. 3 illustrates an embodiment of a process for depositing an example of the transition metal dichalcogenide interlayer disclosed herein on a dielectric;

FIG. 4 illustrates another embodiment of a process for depositing a transition metal dichalcogenide interface layer;

FIGS. 5A-5D illustrate the effect on work function by introducing TMD interface layers;

FIGS. 6A-6B illustrate leakage suppression achieved by a TMD ICL in positive and negative voltage cases according to an embodiment of the present disclosure;

FIG. 7 illustrates leakage current versus equivalent oxide thickness comparing no interlayer, and various TMD interlayers on one side; and

FIG. 8 illustrates leakage data for stacks comprising symmetric and asymmetric TMD bilayer ICL.

### DEFINITIONS

Unless otherwise stated, the following terms used in the specification and claims shall have the following meanings for this application.

In this application, the use of the singular includes the plural, and the words “a,” “an” and “the” mean “at least one” unless specifically stated otherwise. Furthermore, the use of the term “including,” as well as other forms such as “includes” and “included,” is not limiting. Also, terms such as “element” or “component” encompass both elements or components including one unit and elements or components that include more than one unit, unless specifically stated otherwise. As used herein, the conjunction “and” is intended to be inclusive and the conjunction “or” is not intended to be exclusive, unless otherwise indicated. For example, the phrase “or, alternatively” is intended to be exclusive. As used herein, the term “and/or” refers to any combination of the foregoing elements including using a single element.

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

For purposes of this disclosure and the claims hereto, the numbering scheme for the Periodic Table Groups is according to the IUPAC Periodic Table of Elements.

The term “and/or” as used in a phrase such as “A and/or B” herein is intended to include “A and B,” “A or B,” “A” and “B.”

The terms “substituent,” “radical,” “group” and “moiety” may be used interchangeably.

As used herein, the terms “metal-containing complex” (or more simply, “complex”) and “precursor” are used interchangeably and refer to a metal-containing molecule or compound which can be used to prepare a metal-containing film by a deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal nitride film, metal oxide, metal silicide film, a metal carbide film and the like.

As used herein, the terms “elemental metal,” “elemental metal film” and “pure metal film” are used interchangeably and refer to a film which consists of, or consists essentially of, pure metal. For example, an elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. However, a film comprising an elemental metal is distinguished from binary films including a metal and a non-metal (e.g., C, N, O) and ternary films including a metal and two non-metals (e.g., C, N, O), though, a film comprising elemental metal may include some amount of impurities. Unless context dictates otherwise, the term “metal film” shall be interpreted to mean an elemental metal film.

As used herein, the terms “deposition process” and “thermally depositing” are used to refer to any type of deposition technique, including but not limited to, CVD and ALD. In various embodiments, CVD may take the form of conventional (i.e., continuous flow) CVD, liquid injection CVD, plasma-enhanced CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al., J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds. The Royal Society of Chemistry: Cambridge, 2009; Chapter 1, pp 1-36.

Unless otherwise indicated, “alkyl” refers to hydrocarbon groups which can be linear, branched (e.g., methyl, ethyl, propyl, isopropyl, tert-butyl and the like), cyclic (e.g., cyclohexyl, cyclopropyl, cyclopentyl and the like) or multicyclic (e.g., norbornyl, adamantly and the like). Suitable acyclic groups can be methyl, ethyl, n-or iso-propyl, n-, iso, or tert-butyl, linear or branched pentyl, hexyl, heptyl, octyl, decyl, dodecyl, tetradecyl and hexadecyl. Unless otherwise stated, alkyl refers to 1-10 carbon atom moieties. The cyclic alkyl groups may be mono cyclic or polycyclic. Suitable examples of mono-cyclic alkyl groups include substituted cyclopentyl, cyclohexyl, and cycloheptyl groups. The substituents may be any of the acyclic alkyl groups described herein. As mentioned herein the cyclic alkyl groups may have any of the acyclic alkyl groups as substituent. These alkyl moieties may be substituted or unsubstituted.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that any of the incorporated literature and similar materials defines a term in a manner that contradicts the definition of that term in this application, this application controls.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

The problem solved by this disclosure is that ultra-thin high-k capacitors are compromised in their DRAM performance by high leakage current and high equivalent oxide thickness (EOT, a measurement of capacitance and ‘k’). High leakage through the gate dielectric may also compromise the performance of field-effect transistors (FETs).

The present disclosure demonstrates an improvement in high-k capacitor performance when a metallic transition metal dichalcogenide (TMD) layer is introduced between the dielectric layer and an electrode layer, which is applicable for DRAM and FeRAM, or in some embodiments a metallic TMD layer is used instead of the electrode layer. The present disclosure also demonstrates an improvement in transistor performance when a metallic transition metal dichalcogenide (TMD) layer is introduced between the dielectric layer and an electrode layer of a transistor gate, which is applicable for MOSFET, FinFET, and FeFET devices.

Transition metal dichalcogenides should be metallic, i.e., having a non-negligible density of states (DOS) at their intrinsic Fermi level. At least six TMDs (Nb,Ta) (S,Se,Te)₂ possess desired DOS features.

The present disclosure includes conducting metallic TMDs, specifically NbS₂, NbSe₂, TaS₂ and/or TaSe₂ in the 2H (or H) phase are used as an electrode or as a conducting ICL. For the case of an ICL, it can be composed of a single or multiple layers of conducting TMD (multiple layers may have the same or different chemistries), formed between the electrode and the dielectric. In case of a capacitor such an ICL can be used at one or at both electrodes.

In general, TMDs may be semiconducting and metallic, depending on the phase (2H, T, T′, etc.) and chemistry. The unit cell of a 2H phase includes two layers, thus for a monolayer TMDs the name “2H” may be considered as a misnomer (though still routinely used) and could properly be called H phase. For TMDs based on Ta and Nb, e.g., within (Ta,Nb)(S,Se,Te)₂ family, the 2H (or H) phase is metallic and is the lowest-energy phase according to DFT calculations, and thus is expected to be the phase formed during deposition.

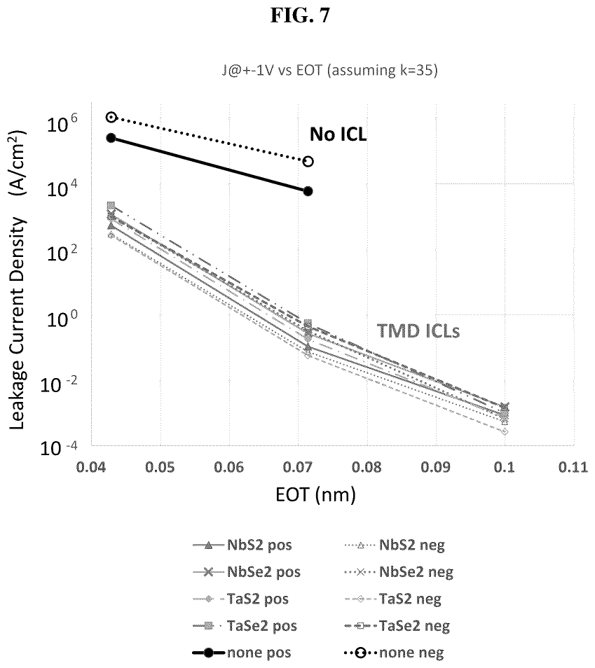

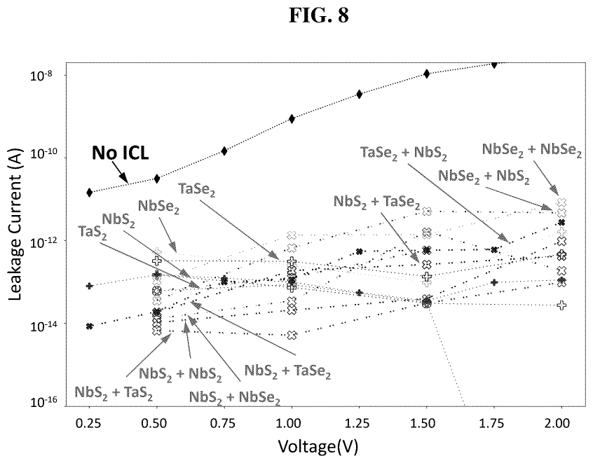

Based on the simulations results of both DOS alignment and the electronic transport, some leakage suppression is demonstrated for most such configurations, with the best results for symmetric stacks including TMD bilayers, consisting either of two layers of NbS₂, or of one NbS₂ and one TaS₂ layer. See FIGS. 7 and 8. Thicker ICLs are possible but may be less desirable if increased device dimensions would result. Use of metallic TMDs as stand-alone electrodes is possible in addition to the use of metallic TMDs as ICLs. Some embodiments include other monolayer, bilayer, or thicker ICLs involving an arbitrary combination (or alloy) of NbS₂, TaS₂, NbSe₂, and/or TaSe₂. Other embodiments include NbTe₂ and TaTe₂ in the 2H (or H) phase.

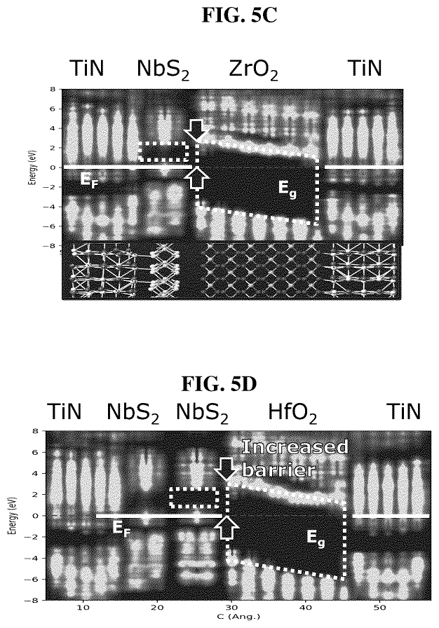

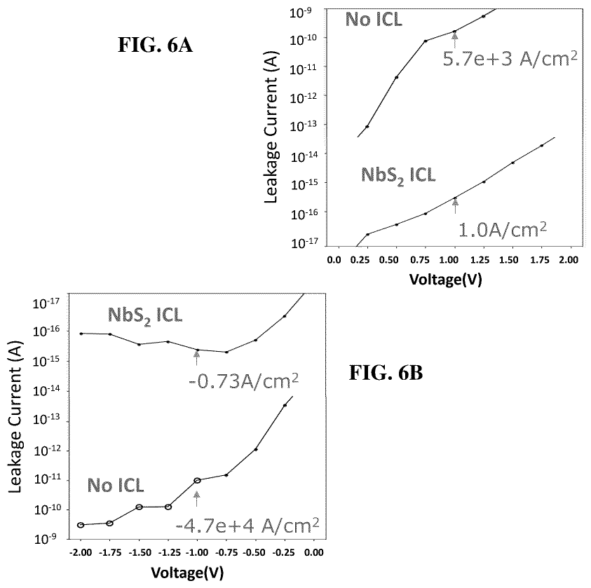

A key advantage is leakage suppression. The mechanism of the leakage suppression may include the increase of the barrier for thermionic electron excitations and for tunnelling electrons, due to an increase of the effective work function upon an introduction of the metallic TMD ICL, as is clearly visible in the results of the simulations using density-functional theory (see FIGS. 5B and 5C). Additionally, the mechanism of leakage suppression may involve the decrease in the local electronic density of states at energies above the Fermi level, reducing the supply of electrons available for tunneling and for thermionic excitations at the negative electrode's side, and/or reducing the availability of the final states for tunneling electrons on the negative electrode's side. Based on simulations, the leakage may be suppressed by an order of magnitude or more compared to the case without ICL, albeit the suppression depends not only on the ICL chemistry but also on the base electrode used, as well as the specific voltage and polarity (especially in case of asymmetric stacks). In particular, in some stacks the leakage current may stop increasing or even decrease slightly as the voltage keeps being increased beyond a certain value, such as beyond ˜0.7 Volt (see FIG. 6B, the negative voltage case), which might be very desirable for some applications (in particular for power electronics applications such as current switches).

By virtue of being metallic and thus acting as a part of an electrode, the thickness of the metallic TMD ICL layer or bilayer does not reduce the effective dielectric constant of the stack. As a result, it does not increase the effective oxide thickness EOT of the dielectric, apart from possible small effect of the van-der-Waals gap between the TMD layer and the dielectric.

Additionally, constituent elements of the metallic transition metal dichalcogenides of the present disclosure are either already used in the semiconductor fabs or are considered on semiconductor manufacturer roadmaps due to being promising liner materials for vias and interconnects. It is a major advantage that these materials are proven in high volume manufacturing, albeit with serving a different function in different parts of integrated devices, as this indicates that semiconductor manufacturers are not likely to face major integration issues introducing these materials in metallic TMD interface layers disclosed herein. At the same time, possibility of leakage reduction due to presence of these materials has been previously unsuspected, and use of these materials as electrodes or as interlayers between an electrode and the dielectric with the purpose of improving leakage vs. capacitance tradeoff has not been suggested before.

Further, thermodynamic analysis and simulations demonstrate that the proposed TMD ICLS are compatible with the popular ZrO₂ and HfO₂ dielectrics (and thus compatibility with the full HZO family of dielectrics is expected).

In some embodiments, the following method of forming stack can be used:
a. TIN BEL deposition, possibly with additional deposition or treatment e.g., such as to form oxynitride in order to optimize TiN work function,
b. NbS₂ bilayer deposited by ALD most preferably in the 2H phase (less preferably as a monolayer or a bilayer with occasional monolayer-only regions) is,
c. then ZrO₂ (or HZO) is deposited by ALD, possibly followed by PDA,
d. then one more NbS₂ bilayer in the 2H phase is deposited by ALD,
e. followed by ALD of TIN TEL.

Optionally, an additional layer such as a thin (0.5 . . . 2.5 Angstrom) oxynitride or TiOx layer may be first deposited on top of the second NbS2 bilayer prior to TEL deposition (prior to step e) to ensure TiN has oxynitride interface. PMA (post metal anneal) may follow step c.

The formed capacitor device is then used for DRAM applications. Either step (b) or step (d) but not both can be omitted.

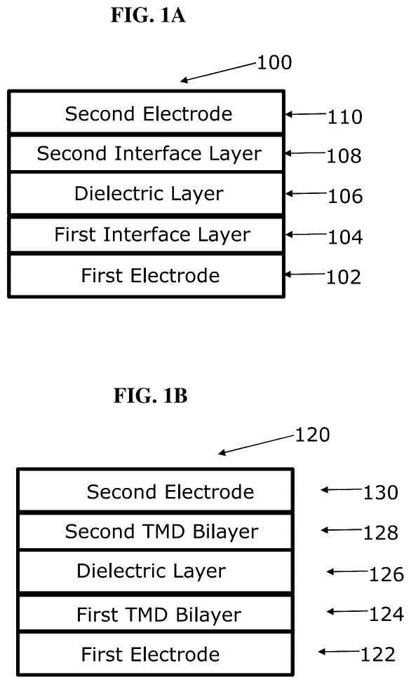

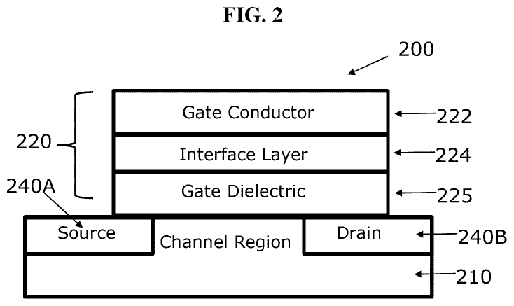

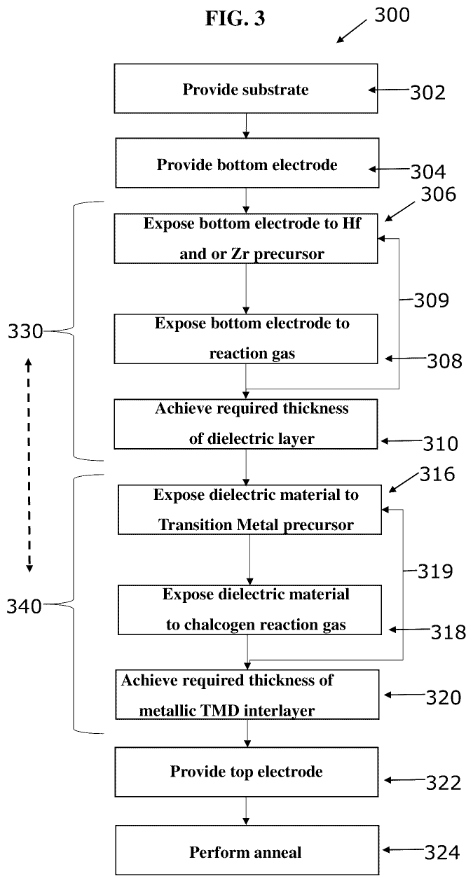

FIGS. 1A and 1B illustrate capacitor structures in accordance with embodiments of the instant disclosure. FIG. 2 illustrates an embodiment of a transistor structure disclosed herein.

FIGS. 1A-1B illustrate configurations of electrode and dielectric according to some embodiments. In FIG. 1A, a capacitor structure 100 can include a dielectric layer 106, such as a high k dielectric layer, sandwiched between electrodes 102 and 110. When a voltage is applied to the electrodes, an electric field can be established across the dielectric layer 170. Thermionic leakage current can be present as the result of the electric field, due to the excitation of charges in the electrodes. The thermionic leakage can affect the operation of the capacitor device. In the illustrate embodiment a bottom interfacial layer 104 is disposed between the bottom electrode 102 and the dielectric material 106; and a top interfacial layer is disposed between the top electrode and the dielectric material 106.

In a preferred embodiment 100, more than one metallic TMD interlayer is provided. A first (bottom) metallic TMD layer 104 is provided between the first (bottom) electrode 102 and the dielectric layer 106, and a second (top) interface layer 108 comprising a metallic TMD is provided between the second (top) electrode 110 and the dielectric layer 106. Sec FIG. 1A. In another embodiment, only one interface layer comprising a metallic TMD is provided.

As shown in FIG. 1B, the illustrated capacitor structure 120 comprises a first (bottom) interface bilayer 124 comprising a metallic TMD is disposed between the first (bottom) electrode 122 and the dielectric material 126; and a second (top) interface layer 128 comprising a metallic transition metal dichalcogenide is disposed between the second (top) electrode 130 and the dielectric material 126. In another embodiment, only one interface TMD bilayer (an interface layer comprising a metallic TMD) is provided.

In another embodiment 120, more than one or two metallic TMD interface layers are provided. A number of metallic TMD layers can comprise an electrode.

In FIG. 2, a transistor structure 200 can be formed on a substrate 210 comprising a semiconducting material such as silicon, may include isolation regions (not shown) to isolate the neighboring devices, source and drain regions 240A and 240B sandwiching a gate electrode 220 including a gate dielectric 225 and a gate conductor 222. Spacers (not shown) may cover the sidewalls of the gate electrode 220. The substrate 210 can be a semiconductor substrate, or any substrates having a layer of semiconductor material. For example, the substrate 210 can be a single crystal silicon substrate. The substrate 210 can be a silicon-germanium substrate or can have a silicon germanium layer disposed on top. The gate conductor 222 can operate as an electrode in the gate stack comprising the gate conductor 222 and the gate dielectric 225. When a voltage is applied to the gate conductor 222, an electric field can be established across the gate dielectric 225, changing the distribution of charges in the substrate 210. Thermionic leakage current can be present as the result of the electric field, due to the excitation of charges in the gate conductor. The thermionic leakage, such as leakage from the gate conductor 222 through the gate dielectric 225, can affect the operation of the transistor. FIG. 2 shows an example of a metal-oxide-semiconductor field effect transistor (MOSFET) structure 200, but the invention is not so limited, and can include any transistor structure, such as insulated-gate bipolar transistors, fin transistors, gate-all-around transistors or double gate transistors. In addition, support structures and devices can also be included, such as silicidation.

An interface layer 224 is provided between the gate dielectric 225 and the gate conductor 222. The interface layer comprises one or more layers of a metallic transition metal dichalcogenide.

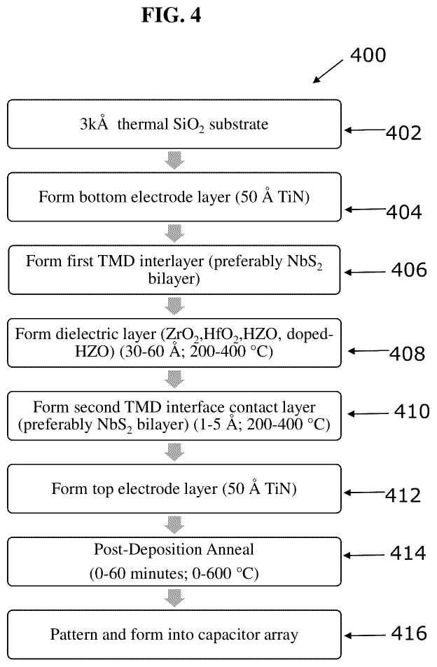

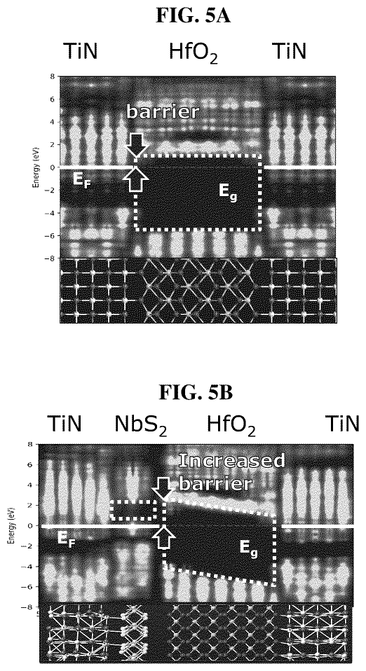

FIGS. 3 and 4 illustrate process flow for integration of TMD ICL between dielectric and bottom electrode or between the dielectric and the top electrode.

FIGS. 5A-5D show the local electronic density of states (DOS) as modeled using density-functional-theory calculations, illustrating the effect on work function by introducing TMD interlayers. FIG. 5A illustrates a TiN—HfO₂—TiN stack. FIG. 5B illustrates a TiN—NbS₂—HfO₂—TiN stack FIG. 5C illustrates a TiN—NbS₂—ZrO₂—TiN stack, and FIG. 5D illustrates a TiN—NbS₂—NbS₂—HfO₂—TiN stack. A work function increase was observed for each ICL considered. A particularly large increase (1.2 eV) was seen for NbS₂. Similarly large increases (1.0 and 1.1 eV) were seen for NbSe₂ and Ta(S/Se)₂, respectively. Note the FIGS. 5B-5D indicate that the local DOS is reduced above the Fermi level of the ICL, which may be contributing to the leakage suppression.

In examples provided in FIGS. 6A-6B, results of density-functional theory simulations using non-equilibrium Green's function method are presented. FIGS. 6A and 6B illustrate leakage current vs applied voltage in the positive voltage case and the negative voltage case, respectively. In both figures, the line labeled “No ICL” illustrates the leakage in MIMCAPs comprised of a TiN—HfO₂—TiN stack (cf. FIG. 5A), and the line labeled “NbS₂ ICL” shows the reduction in leakage with the inclusion of a thin TMD interlayer between the dielectric layer and TiN bottom electrode layer (cf. FIG. 5B). These figures show that introducing the NbS₂ ICL between a TiN electrode and the dielectric results in leakage suppression by several orders of magnitude compared to a stack using TiN electrodes. Additionally, FIG. 6B illustrates that at negative voltages, the leakage does not increase for the range of applied voltages between −0.75V and −2V.

FIG. 7 illustrates that TMD ICL shows a reduction in leakage for the same values of estimated EOT. NbS₂ and TaS₂ devices performed the best in terms of leakage suppression.

FIG. 8 shows leakage data for 1.5 nm stacks comprising symmetric and asymmetric TMD bilayers in comparison with a stack using no ICL. The NbS₂ bilayer and the NbS₂/TaS₂ bilayer devices performed the best in terms of leakage suppression.

The preferred range of thicknesses for this transition metal dichalcogenide film is approximately 0.5 nm to approximately 20 nm and is more preferably approximately 0.6 nm to 1.2 nm if used as an ICL with an additional metallic electrode, or 0.6 nm to 15 nm if used as a standalone electrode. It is also preferable that the materials form films having a thickness of approximately 10 nm and less. In some embodiments it is preferable that the materials form films having a thickness of approximately 5 nm and less.

As discussed above, however, preferred and/or desired thicknesses will change depending on specific application. Thus, as noted previously, in some embodiments the interlayer will be approximately 20 nm or less. In a further aspect the interlayer will be approximately 15 nm or less. In a further aspect, the interlayer will be approximately 10 nm or less. In a further aspect, the interlayer will be approximately 5 nm or less. In a further aspect, the interlayer is approximately 3 nm or less. In a further aspect, the interlayer is approximately 1 nm or less. In a further aspect, the interlayer is approximately 0.5 nm or less. In a further aspect, the interlayer is approximately 0.2 nm or less. In a further aspect, the interlayer has properties of reducing leakage when between approximately 0.005 nm to approximately 1 nm. In a further aspect, the interlayer is between approximately 0.01 nm to approximately 0.5 nm. In a further aspect, the thin films interlayer is between approximately 0.05 nm to approximately 0.4 nm.

### Methods for Preparing and Depositing a Transition Metal Dichalcogenide Interlayer

As noted above, in another aspect the disclosed and claimed subject matter is directed to a process for preparing and/or depositing the interlayers disclosed herein. In this process, the disclosed and claimed interlayers are prepared by iterative depositions and purges (i) of a metallocene precursor and (ii) a reactant. Although ALD is a preferred vapor deposition technique, any suitable vapor phase deposition technique can be utilized, such as CVD or pulsed CVD. Thus, for example an ALD cycle could be replaced by a CVD process in which metallocene precursor and reactant are provided as a mixture in vapor and provided simultaneously to substrate.

### A. Transition Metal Precursors

As noted above, preferred transition metal precursors include: niobium or tantalum. Niobium precursors include: niobium chloride (NbCl₅), tert-butylimino tri(diethylamino) niobium, tert-butylimino tri(dimethylamino) niobium, tert-butylimino tri(ethylmethylamino) niobium, ethylimino tri(diethylamino) niobium, ethylimino tri(dimethylamino) niobium, ethylimino tri(ethylmethylamino) niobium, tert-amylimino tri(dimethylamino) niobium, tert-amylimino tri(diethylamino)tantalum, pentakis(dimethylamino)niobium, and tert-amylimino tri(ethylmethylamino)niobium. Tantalum precursors include tantalum chloride (TaCl5), tert-butylimino tri(diethylamino)tantalum (TBTDET), tert-butylimino tri(dimethylamino)tantalum (TBTDMT), tert-butylimino tri(ethylmethylamino)tantalum (TBTEMT), ethylimino tri(diethylamino)tantalum (EITDET), ethylimino tri(dimethylamino)tantalum (EITDMT), ethylimino tri(ethylmethylamino)tantalum (EITEMT), tert-amylimino tri(dimethylamino)tantalum (TAIMAT), tert-amylimino tri(diethylamino)tantalum, pentakis(dimethylamino)tantalum, and tert-amylimino tri(ethylmethylamino)tantalum.

In general, suitable precursors are able to be deposited between approximately 200° C. and approximately 570° C. depending on the composition of the material, substrate, and reactor design, among other factors. A preferred temperature is approximately 280° C. (or generally between approximately 250° C. and approximately 400° C.), and the preferred temperature range is below approximately 450° C. and more preferably below approximately 340° C. However, those skilled in the art should recognize that other temperatures may be possible depending on the specific precursor used and that such precursors also fall within the scope of the disclosed and claimed subject matter. It should further be noted that with certain precursors besides the ones listed here, decomposition of the precursor can occur within the temperature range described. Decomposition products, in particular carbon and organic species, can become incorporated in the deposited transition metal dichalcogenide material.

### B. Chalcogen Precursors

In certain embodiments, excess H₂S, H₂Se, and/or H₂Te both supply the excess chalcogenide in the process, but also ensure a reducing environment for the reaction.

### C. Process Steps

FIG. 3 illustrates an embodiment of a process for preparing and depositing the TMD interlayer descried herein. As illustrated, substrate undergoes an ALD cycle in which substrate is exposed to vapor to form and deposit a bottom electrode. As illustrated, substrate undergoes an ALD cycle in which substrate is exposed to vapor to form and deposit a bottom electrode. For example, energy can subsequently be applied to the material by, but not limited to, thermal, plasma, pulsed plasma, helicon plasma, high density plasma, inductively coupled plasma, X-ray, e-beam, photon, remote plasma methods, and combinations thereof.

The constituents of vapor change during ALD cycle. In particular, substrate is alternatingly exposed to metallocene precursor followed by a purge and then exposed to reactant followed by another purge. This process continues until a desired thickness for layer is obtained.

The substrate on which the bottom electrode is formed as layer can include any suitable material, including semiconducting materials like silicon, germanium, III-V materials, transition metal dichalcogenides, and mixtures thereof, metals and conductive ceramics like titanium nitride, titanium, tantalum, tantalum nitride, tungsten, platinum, rhodium, molybdenum, cobalt, ruthenium, palladium, or mixtures thereof, or dielectrics like silicon oxide, silicon nitride, aluminum oxide, titanium oxide, other ferroelectric materials, including compositions of hafnium oxide and zirconium oxide, magnetic materials, and mixtures or stacks thereof.

Optionally, substrate can be patterned or textured, as appropriate, with any suitable topography, including flat surfaces, trenches, vias, or nanostructured surfaces. This list represents typical substrates that may be useful in ferroelectric applications, but should not be considered limiting, as many other suitable compositions and surface patterns would be obvious to those skilled in the art. In this regard, it is known that the substrate can have some influence on the atomic arrangement and phase of the film formed thereon, including affecting the crystalline orientation and crystallization temperature of the film.

FIG. 3 illustrates a process 300 of providing a substrate 302, providing a bottom electrode 304, exposing the bottom electrode to Hf and or Zr precursor 306, exposing the bottom electrode to reaction gas 308, repeating 309 steps 306 and 308 to achieve the required thickness of dielectric layer 310, exposing the dielectric layer to a transition metal precursor 316, exposing the dielectric material to a chalcogen precursor 318, repeating 319 steps 316 and 318 to achieve the required thickness of TMD interlayer 320, providing a top electrode 322, and performing an annealing step 324.

In the illustrated embodiment, dielectric is deposited 330 before the TMD interlayer is deposited 340, resulting in the TMD layer being deposited between the top electrode and the dielectric layer. In another embodiment process 330 and process 340 can be swapped, resulting in the TMD layer being deposited between the dielectric layer and the bottom electrode.

Similarly, the process of depositing one or more TMD interlayers can occur prior to depositing the dielectric and after depositing the dielectric to achieve TMD interface layers on either side of the dielectric layer as shown in the embodiments of FIGS. 1A and 1B.

In a preferred embodiment, all steps 302 to 324 are performed at a temperature of less than 400 degrees Celsius.

In an illustrated embodiment, the TMD interlayer is deposited 340 by repeating step 319 the transition metal dichalcogenide deposition resulting in a bilayer TMD. Preferably the bilayer comprises two layers of NbS₂ or a first layer of NbS₂ and a second layer of TaS₂.

In other embodiments, a mixed hafnium oxide and zirconium oxide dielectric material is prepared and deposited as a layer. The dielectric material may be prepared and deposited as layer from the vapor by ALD by alternating First Cycle 303 (which includes the steps of (i) pulsing (MeCp)₂Zr(OMe)Me 304, (ii) purging, (iii) pulsing ozone 305 and (iv) purging) and Second Cycle 306 (which includes the steps of (i) pulsing (MeCp)₂Hf(OMe)Me 307, (ii) purging, (iii) pulsing ozone 308 and (iv) purging).

Those skilled in the art will recognize that other precursors, such as (MeCp)₂HfMe₂ and (MeCp)₂ZrMe₂ and other reactants, such as water, hydrogen peroxide or oxygen plasma, may also or alternatively be used. Those skilled in the art will further recognize that the pulsing and purging times can each respectively vary depending on equipment. In one embodiment, pulses last from approximately 2 to approximately 3 seconds followed by a purge of approximately 10seconds. In another embodiment, pulses last from approximately 10 to approximately 15 seconds followed by a purge of approximately 30 seconds to approximately 60 seconds. In another embodiment, the order in which the precursors are deposited can be reversed.

In some embodiments, the annealing is performed in the presence of argon at a pressure in the range of 1 to 20 Torr (e.g., at 7 Torr) for between 1 and 60 minutes (e.g., for 10 minutes).

FIG. 4 illustrates another embodiment of a process for preparing and depositing the TMD interlayer materials descried herein. In this embodiment, a hafnium oxide, a zirconium oxide, or a mixed hafnium oxide and zirconium oxide dielectric material is prepared and deposited as a layer with a thickness of approximately 30-60 Å is on a stacked substrate of TiN (which may or may not be in direct contact with the dielectric material), a thermally grown SiO₂ layer and a Si wafer. Layer was formed without further thermal processing or capping.

The process 400 includes providing a substrate 402 of 3 kÅ SiO₂, forming a bottom electrode 404, preferably via ALD, forming an optional interlayer (not shown) comprising a metal oxynitride, forming a first transition metal dichalcogenide layer 406, wherein the TMD layer is preferably a bilayer of NbS₂, forming a dielectric layer 408, wherein the dielectric layer has a thickness of about 30-60Å and is formed at a temperature of between 200 and 400° C.

Forming the first TMD interlayer 406 includes exposing the bottom electrode layer (and/or an optional metal oxynitride interlayer) to a transition metal precursor, exposing the bottom electrode to a chalcogen-rich precursor or reaction gas, and repeating the steps to achieve the required thickness of TMD interlayer.

The step of forming the dielectric layer 408 may include exposing the bottom electrode to Hf and or Zr precursor, exposing the bottom electrode to reaction gas, and repeating these steps to achieve the required thickness of dielectric layer. Forming the second TMD interlayer 410 includes exposing the dielectric layer to a transition metal precursor, exposing the dielectric material to chalcogen-rich reaction gas, and repeating the steps to achieve the required thickness of TMD interlayer.

Forming a top electrode 412 is preferably performed using an ALD process and the top electrode preferably comprises TiN and is about 50 Å thick.

A post deposition anneal step 414 is performed for up to an hour at a temperature of up to about 600° C.

A step of patterning and forming a capacitor array 416 is performed. In the preferred embodiment, all steps 402 to 416 are performed at a temperature of less than 600 degrees Celsius.

In certain embodiments, the capacitor can be incorporated into a crossbar array or a memory unit cell. In certain embodiments, the capacitor can be incorporated into a neuromorphic computing chip or a synaptic device such as a synaptic memristor or a synaptic transistor.

An embodiment of a process for preparing and depositing the transition metal dichalcogenide interlayers descried herein using ALD. The method includes several steps that can be augmented with additional and/or optional steps. Step 1 includes providing a substrate at a deposition temperature of between approximately 265° C. and approximately 500° C., but that is preferably at or around approximately 300° C. (e.g., above approximately 285° C. and at or below approximately 300° C.) and below 340° C. Step 2 includes (i) exposing the substrate to a first precursor containing a transition metal that does not decompose at the deposition temperature and (ii) purging. Step 3 includes (i) exposing the substrate to a reaction gas containing oxygen and (ii) purging. Step 4 includes (i) exposing the substrate to a second precursor containing a chalcogen that does not decompose at the deposition temperature and (ii) purging. Step 5 includes exposing the substrate to a reaction gas containing oxygen. Optional Step 6 includes repeating Steps 2-5 until a film of transition metal dichalcogenide of desired thickness is formed on the dielectric material.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

### Device

The bottom (first) electrode and the top (second) electrode may be metallic or semiconducting electrodes having a thickness to ensure good conduction. In the illustrated embodiment, the top electrode comprises titanium nitride. In other embodiments, the top electrode may comprise any of titanium nitride, tungsten, nickel, ruthenium, platinum, and aluminum. In an illustrated embodiment, 50 nm thick TiN is used.

In the illustrated embodiment, the bottom electrode comprises titanium nitride. In other embodiments, the top electrode may comprise any of titanium nitride, tungsten, ruthenium, platinum, and aluminum. In the illustrated embodiment, 50 nm thick TiN is used.

The TMD ICL can be grown according to the following method:
1. The wafer heats to operating temperature over ten minutes at a spacing of 0.3 in from the reactor showerhead. The pressure in the reactor is throttled to 1 Torr under 3000 sccm total Ar gas flows from multiple introduction points.
2. A transition metal precursor, preferably niobium precursor NbCl₅, is pulsed through a bubbler with 120 sccm of carrier gas for a duration of 15 seconds. 400 sccm of carrier gas is co-injected from the top of the monoblock to carry the precursor. 25 sccm of Ar is injected from the center port of the chamber, chamber is throttled to 1 Torr.
3. Chamber is purged from excess Nb gas and reaction byproducts for 20 seconds under a fully open throttle. The total Ar flow rate is 2625 sccm from multiple introduction points. The Nb bubbler line is purged directly to a divert pump under 120 sccm of carrier gas flow.
4. A chalcogen precursor such as H₂S is pulsed for 15 seconds at a flow rate of 800 sccm into a chamber with 925 sccm total mass flow rate, the pressure is throttled to 1 Torr
5. Chamber is purged from excess H₂S and reaction byproducts for 15 seconds under a fully open throttle. The total Ar flow rate is 2625 sccm from multiple introduction points to purge the chamber.
6. Steps 2-5 comprise a complete TMD ICL ALD cycle which can be repeated to achieve an ICL with varied thickness.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

Although the invention has been described and illustrated with a certain degree of particularity, it is understood that the disclosure has been made only by way of example, and that numerous changes in the conditions and order of steps can be resorted to by those skilled in the art without departing from the spirit and scope of the invention.

1. A capacitor comprising:
a first electrode;
a second electrode;
a dielectric layer between the first electrode and the second electrode; and
an interface layer, wherein the interface layer comprises a metallic transition metal dichalcogenide.

2. The capacitor of claim 1, wherein the metallic transition metal dichalcogenide comprises NbS₂, NbSe₂, NbTe₂, TaS₂, TaSe₂, TaTe₂, or combinations thereof.

3. The capacitor of claim 1, wherein the dielectric layer comprises ZrO₂, HfO₂, TiO₂, MoO₂, or combinations thereof.

4. The capacitor of claim 1, wherein the interface layer has a thickness ranging from about 5 Å to about 20 Å.

5. The capacitor of claim 1, wherein the interface layer is disposed between the second electrode and the dielectric layer.

6. The capacitor of claim 1, wherein the interface layer is disposed between the first electrode and the dielectric layer.

7. The capacitor of claim 1, wherein the interface layer is a bilayer.

8. The capacitor of claim 7, wherein the bilayer comprises a first layer of the metallic transition metal dichalcogenide and a second layer of a second metallic transition metal dichalcogenide.

9. The capacitor of claim 1, wherein a further interface layer is provided between the first electrode and the dielectric film, between the second electrode and the dielectric film, between the interface layer and the first electrode, or between the interface layer and the second electrode; and
wherein the further interface layer comprises an oxide of a metal element.

10. The capacitor of claim 1, wherein the second electrode is a bottom electrode comprising a metal nitride represented by MN;
wherein M is a metal element, wherein M is Be, B, Na, Mg, Al, Si, K, Ca, Sc, Ti, V, Cr, Mn, Fe, Co, Ni, Cu, Zn, Ga, Ge, Rb, Sr, Y, Zr, Nb, Mo, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, or Bi; and
wherein N is nitrogen.

11. The capacitor of claim 9, wherein the further interface layer comprises a metal oxynitride represented by M′OxNy;
wherein M′ is a metal element, wherein M′ is Li, Be, B, N, Na, Mg, Al, Si, P, K, Ca, Sc, Ti, V, Cr, Mn, Fe, Co, Ni, Cu, Zn, Ga, Ge, As, Se, Rb, Sr, Y, Zr, Nb, Mo, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, or Bi;
wherein N is nitrogen; and
wherein O is oxygen.

12. The capacitor of claim 1, wherein the first electrode directly contacts a bottom surface of the interface layer, and the dielectric film directly contacts a top surface of the interface layer; and/or
wherein the second electrode directly contacts a top surface of the interface layer, and the dielectric film directly contacts a bottom surface of the interface layer.

13. A semiconductor device comprising:
a semiconducting material;
a gate structure on the semiconducting material; and
the gate structure comprising a gate dielectric disposed on the semiconducting material, an interface layer disposed on the gate dielectric, and a gate conductor disposed on the interface layer; and
wherein the interface layer comprises a metallic transition metal dichalcogenide.

14. The semiconductor device of claim 13, wherein the interface layer has a thickness of between about 5 Å and about 20 Å, more preferably from about 6 Å to about 12 Å.

15. The semiconductor device of claim 13, wherein the interface layer is a bilayer; and
wherein the bilayer comprises a first layer of the metallic transition metal dichalcogenide and a second layer of the metallic transition metal dichalcogenide; or
wherein the bilayer comprises a first layer of the metallic transition metal dichalcogenide and a second layer of a second metallic transition metal dichalcogenide.

16. The semiconductor device of claim 13, wherein the metallic transition metal dichalcogenide comprises NbS₂, NbSe₂, NbTe₂, TaS₂, TaSe₂, TaTe₂, or combinations thereof.

17. The semiconductor device of claim 13, wherein the gate dielectric directly contacts a bottom surface of the interface layer, and the gate conductor directly contacts a top surface of the interface layer.

18. A method of fabricating a capacitor, the method comprising:
forming a first electrode by atomic layer deposition;
forming a dielectric layer by atomic layer deposition;
forming one or more interface layers comprising a metallic transition metal dichalcogenide by atomic layer deposition; and
forming a second electrode by atomic layer deposition.

19. The method of claim 18, further comprising forming one or more further interface layers comprising the metallic transition metal dichalcogenide or a further metallic transitional metal dichalcogenide.

20. The method of claim 19, wherein the metallic transition metal dichalcogenide or the further metallic transition metal dichalcogenide comprises NbS₂, NbSe₂, TaS₂, TaSe₂, or combinations thereof.
